(19) United States
(12) Patent Application Publication
(10) Pub. No.: US 2024/0133971 A1
(43) Pub. Date: Apr. 25, 2024

(54) METHOD AND SYSTEM FOR ESTIMATING SHORT CIRCUIT RESISTANCE IN BATTERY USING OPEN CELL VOLTAGE

(71) Applicant: SAMSUNG ELECTRONICS CO., LTD., Suwon-si (KR)

(72) Inventors: Sivagaminathan BALASUBRAMANIAN, Bengaluru (IN); Jinho KIM, Suwon-si (KR); Myeongjae LEE, Suwon-si (KR)

(73) Assignee: SAMSUNG ELECTRONICS CO., LTD., Suwon-si (KR)

(21) Appl. No.: 18/487,624

(22) Filed: Oct. 16, 2023

(30) Foreign Application Priority Data
Oct. 14, 2022 (IN) 202241058817
Apr. 13, 2023 (KR) 10-2023-0048644

(51) Int. Cl. G01R 31/392; G01R 31/36; G01R 31/367; G01R 31/3835

(52) U.S. Cl. CPC G01R 31/392; G01R 31/3648; G01R 31/367; G01R 31/3835

(57) ABSTRACT

A method of estimating a short circuit resistance in a battery using open cell voltage (OCV) includes: determining a rest period OCV for a rest period of the battery; determining a no-short OCV of a no-short condition based on a predetermined parameter, a first state-of-health (SoH) parameter, and a first temperature of the battery; determining that an internal short is present in the battery based on the no-short OCV and the rest period OCV, and based thereon extending the rest period of the battery; determining an extended OCV of the battery for the extended rest period based on the predetermined parameter, a second SoH parameter, and a second temperature of the battery; and estimating the short circuit resistance based on the no-short OCV, the predetermined parameter, and the extended OCV.

### CROSS-REFERENCE TO RELATED APPLICATIONS

This application claims the benefit under 35 USC § 119(a) of Indian Patent Application No. 202241058817 filed on Oct. 14, 2022, in the Indian Patent Office, and Korean Patent Application No. 10-2023-0048644 filed on Apr. 13, 2023, in the Korean Intellectual Property Office, the entire disclosures of which are incorporated herein by reference for all purposes.

### BACKGROUND

### 1. Field

The following description relates to a method and system for estimating a short circuit resistance in a battery using an open cell voltage (OCV).

### 2. Description of Related Art

In general, many consumers are using devices such as mobile phones, laptops, tablets, and smartwatches. Usually, a rechargeable battery (e.g., a lithium-ion battery (LIB)) provides portable electricity and power to such devices. Also, electric vehicles are operated using electrical energy stored in a rechargeable battery. However, such rechargeable batteries may be susceptible to safety issues because of internal short circuits. For example, fast charging accelerates degradation through lithium plating, and such accretion may cause a short circuit. When a short circuit is detected during in its initial stage, a catastrophe such as fire may be prevented. Accurate determination of the severity of a short circuit may help determine an appropriate selection of countermeasures such as shutting down, restricting a state of charge (SOC) window, or informing a user. Hence, detecting early-stage short circuits (e.g., short circuit resistance <500 Ω) and estimating a short circuit resistance can enhance the reliability and safety of lithium-ion battery (LIB) powered devices.

However, the influence of early-stage shorts or soft shorts (>50 Ω) on a battery is feeble, and battery signatures due to short circuit faults are indistinguishable from a healthy cell. Further, existing methods for detecting early short circuits are impractical for device implementation because variations in operating temperatures and properties due to cycle life are not considered. The variations may cause inaccuracy in determining a short circuit resistance (Rₛₕₒᵣₜ), particularly if Rₛₕₒᵣₜ is greater than 50 Ω.

Therefore, there is a need for an improved implementable method on devices for early short circuit detection and estimation of a short resistance.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a method of estimating a short circuit resistance in a battery using open cell voltage (OCV) includes: determining a rest period OCV for a rest period of the battery; determining a no-short OCV of a no-short condition based on a predetermined parameter, a first state-of-health (SoH) parameter, and a first temperature of the battery; determining that an internal short is present in the battery based on the no-short OCV and the rest period OCV, and based thereon extending the rest period of the battery; determining an extended OCV of the battery for the extended rest period based on the predetermined parameter, a second SoH parameter, and a second temperature of the battery; and estimating the short circuit resistance based on the no-short OCV, the predetermined parameter, and the extended OCV.

The predetermined parameter may define the effect of different temperatures on battery life of the battery.

The determining that an internal short is present in the battery may include: determining that a difference between the no-short OCV and the rest period OCV exceeds a threshold.

The estimating of the short circuit resistance may be based on a determined parameter and a difference between the extended OCV and the no-short OCV.

The estimating of the short circuit resistance may include: determining a no-short slope of the no-short OCV based on the first temperature and the first SoH parameter; determining an extended slope of the extended OCV based on the second temperature and the second SoH parameter; and estimating the short circuit resistance based on a predetermined parameter and a difference between the extended slope and the no-short slope.

The short circuit resistance may be estimated using a predefined equation.

The predefined equation may include a ratio of (i) a sensitivity of battery life of the battery to temperature to (ii) a difference between the no-short OCV and the extended OCV.

The predetermined parameter may be a parameter of the battery corresponding to when the battery was manufactured.

The first SoH parameter may obtained from a battery management system (BMS).

In another general aspect, a system for estimating a short circuit resistance in a battery using open cell voltage (OCV) includes: a processor coupled to a memory and a battery management system (BMS); the memory storing instructions configured to cause the processor to: determine a rest period OCV for a rest period of the battery; determine a no-short OCV of a no-short condition based on a predetermined parameter, a first state-of-health (SoH) parameter obtained from the BMS, and a first temperature of the battery; determine that an internal short is present in the battery based on the no-short OCV and the rest period OCV, and based thereon, extend the rest period of the battery; determine an extended OCV of the battery for the extended rest period based on the predetermined parameter, a second SoH parameter obtained from the BMS, and a second temperature of the battery; and estimate the short circuit resistance based on the no-short OCV, the predetermined parameter, and the extended OCV.

The predetermined parameter may define the effect of different temperatures on battery life of the battery.

The instructions may be further configured to cause the processor to: determine that an internal short is present in the battery in response to a difference between the no-short OCV and the rest period OCV exceeding a threshold.

The instructions may be further configured to cause the processor to: estimate the short circuit resistance based on a predetermined parameter and a difference between the extended OCV and the no-short OCV.

The instructions may be further configured to cause the processor to: determine a no-short slope of the no-short OCV based on at least the first temperature and the first SoH parameter; determine an extended slope of the extended OCV based on at least the second temperature and the second SoH parameter; and estimate the short circuit resistance based on the predetermined parameter and a difference between the extended slope and the no-short slope.

The instructions may be further configured to cause the processor to estimate the short circuit resistance using a predefined equation.

The predefined equation may include a ratio of (i) a sensitivity of battery life of the battery to temperature to (ii) a difference between the no-short OCV and the extended OCV.

The predefined parameter may be a parameter of the battery corresponding to a time of manufacture of the battery.

In another general aspect, a method of determining a short circuit resistance of a battery includes: determining a first OCV corresponding to a rest period of the battery; determining, based on a first SOH of the battery and a first temperature of the battery, a second OCV corresponding to a no-short condition of the battery; based on the first OCV and the second OCV, increasing a rest period duration of the battery; determining, based on a second SOH of the battery and a second temperature of the battery, a third OCV corresponding to the increased rest period duration; and determining the short circuit resistance based on the second OCV and the third OCV.

The determining the second OCV, the third OCV, and the short circuit resistance may be further based on a predetermined parameter of the battery.

The short circuit resistance may be determined based on a difference between second OCV and the third OCV.

Other features and aspects will be apparent from the following detailed description, the drawings, and the claims.

### BRIEF DESCRIPTION OF THE DRAWINGS

FIG. 1 illustrates an example device for detecting a short circuit in a battery, according to one or more embodiments.

FIG. 2 illustrates an example battery of a device, according to one or more embodiments.

FIG. 3 illustrates an example method of estimating a short circuit resistance in a battery using an open cell voltage (OCV), according to one or more embodiments.

FIG. 4 illustrates an example system for estimating a short circuit resistance in a battery using an OCV, according to one or more embodiments.

FIGS. 5A to 5C illustrate examples of the effect of temperature at different short circuit resistances on an OCV profile of a battery, according to one or more embodiments.

FIGS. 6A to 6C illustrate examples of the effect of temperature at different short circuit resistances on an average OCV value and an OCV slope of a battery, according to one or more embodiments.

Further, skilled artisans will appreciate that elements in the drawings are illustrated for simplicity and may not be necessarily drawn to scale. For example, the flowcharts illustrate the method in terms of the most prominent operations involved to help to improve understanding of aspects of the present disclosure. Furthermore, in terms of the construction of a system, one or more components of the system may be represented in the drawings by conventional symbols, and the drawings may show only those particular details that are pertinent to understanding the examples of the present disclosure so as not to obscure the drawings with details that will be readily apparent to those skilled in the art having the benefit of the description herein.

Throughout the drawings and the detailed description, unless otherwise described or provided, it may be understood that the same or like drawing reference numerals refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

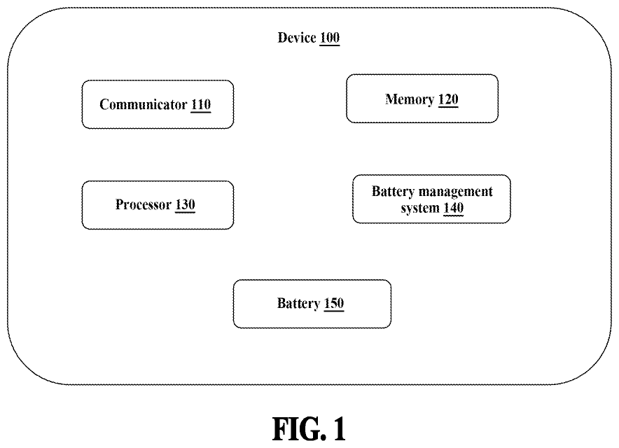

FIG. 1 illustrates an example device for detecting a short circuit in a battery, according to one or more embodiments.

According to an example, a device 100 may estimate a short circuit resistance in a battery using an open cell voltage (OCV). The device 100 may be, for example, a mobile phone, a smartphone, a tablet computer, a handheld device, a laptop, a wearable computing device, an Internet of Things (IoT) device, a digital camera, or the like. However, examples are not limited thereto. The device 100 may also be, or may include, a device or system for estimating a short circuit resistance in a battery pack of an electric vehicle or a battery short circuit detecting device for electric vehicles, or the like.

Referring to FIG. 1, the device 100 may include a communicator 110, a memory 120, a processor 130, a battery management system (BMS) 140, and a battery 150.

The communicator 110 may be configured to communicate internally between internal units of the device 100 and external devices such as a printer, a fax machine, and the like, via one or more networks. The memory 120 may store instructions to be executed by the processor 130. The processor 130 may be configured to execute the instructions stored in the memory 120 and perform various operations.

The memory 120 may include one or more computer-readable storage media. The memory 120 may include non-volatile storage elements. Examples of such non-volatile storage elements may include magnetic hard discs, optical discs, floppy discs, flash memories, or forms of erasable programmable read-only memories (EPROM) or electrically erasable programmable read-only memories (EEPROM), but not signals per se. In addition, the memory 120 may, in some examples, be considered a non-transitory storage medium. The term “non-transitory” may indicate that a storage medium is not embodied in a carrier wave or a propagated signal. However, the term “non-transitory” should not be interpreted as meaning that the memory 120 is non-movable. In some examples, the non-transitory storage medium (e.g., a random-access memory (RAM) or a cache) may store data that may change over time.

The BMS 140 may be coupled to the memory 120, the processor 130, and the battery 150. The BMS 140 may be an electronic system that manages the battery 150, for example, a rechargeable battery (a cell or a battery pack). The BMS 140 may be configured to manage the charging and discharging of the battery 150 (e.g., by providing power and/or regulating an external power source), to provide notifications about a state of the battery 150, and to provide critical safeguards to protect the battery 150 from damage, such as short circuit detection. The battery 150 may be a rechargeable battery. An example of the rechargeable battery may be a lithium-ion battery (LIB).

Although FIG. 1 illustrates hardware elements of the device 100, it is to be understood that other examples are not limited thereto. In other examples, the device 100 may include fewer or more elements. Furthermore, labels or names of the elements are used only for illustrative purposes and do not limit the scope of the present disclosure.

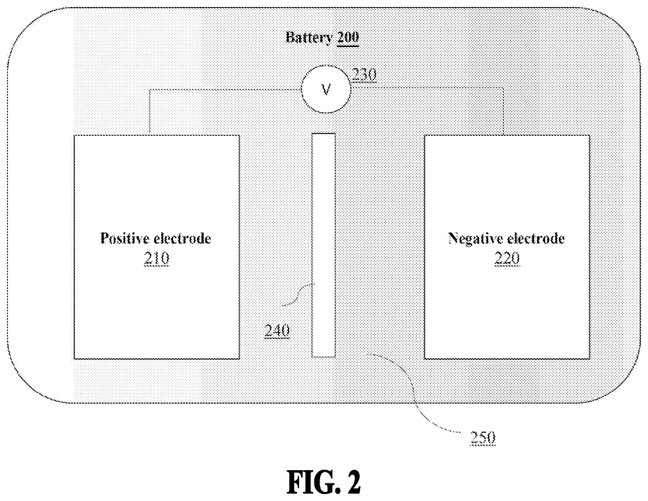

FIG. 2 illustrates an example battery 200 of a device, according to one or more embodiments.

In an example, the battery 200 may include any battery (e.g., an LIB, a lithium-polymer battery, etc.) having a membrane (e.g., a separator) that separates a positive electrode and a negative electrode. The battery 200 may include various shapes and sizes depending on a shape and size of a device (e.g., the device 100 of FIG. 1) and an amount of power required by the device 100. As illustrated in FIG. 2, the battery 200 may include a positive electrode 210, a negative electrode 220, a voltage source 230, a separator 240, and/or an electrolyte 250. In an implementation, the battery 200 may provide power to components of the device 100.

In an example, the positive electrode 210 may include an electrode through which a positive current flows into a polarized electrical device. A shape and size of the positive electrode 210 may vary depending on a shape and size of the battery 200 and be made of various materials.

In an example, the negative electrode 220 may include an electrode through which the positive current flows out of the polarized electrical device. A shape and size of the negative electrode 220 may vary depending on the shape and size of the battery 200 and may be made of various materials.

In an example, the voltage source 230 may be used to charge the battery 200.

In an example, the separator 240 may separate the positive electrode 210 and the negative electrode 220 and include a membrane (e.g., a microporous membrane). A shape and size of the separator 240 may vary depending on the shape and size of the battery 200.

In an example, the electrolyte 250 may include any liquid substance which acts as a medium to conduct electricity between the positive electrode 210 and the negative electrode 220 and store energy in the positive electrode 210 and the negative electrode 220. The electrolyte 250 may depend on a type and purpose of the battery 200.

In an example, the battery 200 may be, or may include, an LIB. Although FIG. 2 illustrates exemplary components of the battery 200, in other examples, the battery 200 may include a smaller number of components, different components, or additional components compared to the components illustrated in FIG. 2.

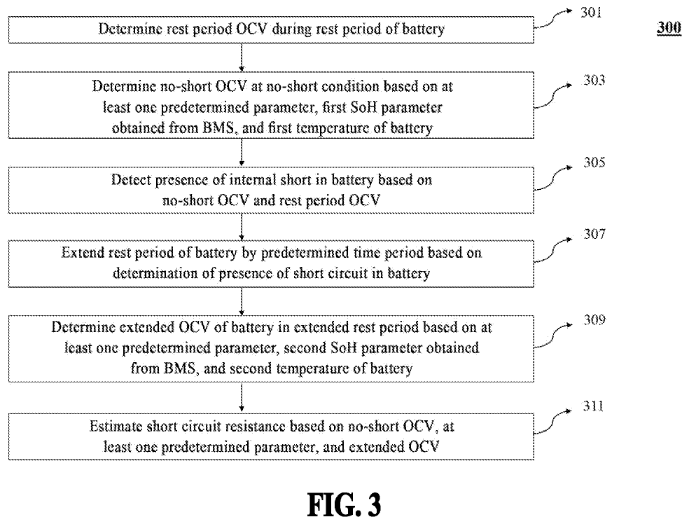

In order to prevent any health and safety issues associated with short circuits of the battery 200, in an implementation described below in connection with FIGS. 3 to 5, a short circuit resistance in the battery 200 may be estimated.

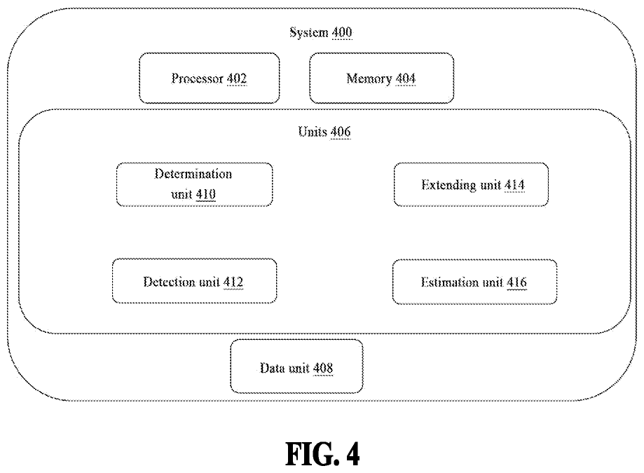

FIG. 3 illustrates an example of a method 300 of estimating a short circuit resistance in a battery using an OCV, according to one or more embodiments. FIG. 4 illustrates an example of a system 400 for estimating a short circuit resistance in a battery using an OCV, according to one or more embodiments. FIGS. 3 and 4 are described together.

The system 400 may be a part of a BMS (e.g., the BMS 140 of FIG. 1). In another example, the system 400 may be a part of a device (e.g., the device 100 of FIG. 1) and may be connected to the BMS 140. In another example, the system 400 may be connected to the device 100 and thereby may be connected to the BMS 140.

The system 400 may include a processor 402, a memory 404, units 406, and a data unit 408, but examples are not limited thereto. The units 406 and the memory 404 may be connected to the processor 402.

The processor 402 may be a single processing unit or several units, any of which may include a plurality of computing units. The processor 402 may be implemented as one or more microprocessors, microcomputers, microcontrollers, digital signal processors, central processing units (CPUs), state machines, logic circuits, and/or any devices that manipulate signals based on operational instructions. Among other capabilities, the processor 402 may be configured to fetch and execute computer-readable instructions and data stored in the memory 404.

The memory 404 may include any non-transitory computer-readable medium known in the art including, for example, a volatile memory, such as a static RAM (SRAM) and a dynamic RAM (DRAM), and/or a non-volatile memory, such as a ROM, an EPROM, flash memories, hard discs, optical discs, and magnetic tapes.

The units 406, amongst other things, may be implemented as routines, programs (sets of instructions), objects, components, data structures, code, or the like, which perform particular tasks or implement data types. The units 406 may also be implemented as signal processor(s), state machine(s), logic circuits, and/or any other devices or components that control signals based on operational instructions.

In addition, the units 406 may be implemented by hardware, instructions executed by a processing unit, or a combination thereof. The processing unit may include a computer, a processor, such as the processor 402, a state machine, a logic array, or any other suitable devices capable of processing instructions. The processing unit may be a general-purpose processor that executes instructions to cause the general-purpose processor to perform required tasks or, the processing unit may be dedicated to performing required functions. In another example, the units 406 may be machine-readable instructions (software) which, when executed by a processor/processing unit, perform any of the described functionalities.

In an example, the units 406 may include a determination unit 410, a detection unit 412, an extending unit 414, and an estimation unit 416.

The units 410, 412, 414, and 416 may communicate with each other. In an example, the units 410, 412, 414, and 416 may be a part of, or implemented by, the processor 402, and in this case, the processor 402 may be configured to perform functions of the units 410, 412, 414, and 416.

The data unit 408 may store data processed, received, and generated by one or more of the units (e.g., the determination unit 410, the detection unit 412, the extending unit 414, and the estimation unit 416).

Referring to FIG. 1, the memory 120 and the processor 130 of the device 100 may be coupled to the BMS 140. In an example, the memory 120 and the processor 130 of the device 100 may perform functions of the processor 402 and the memory 404 of the system 400.

Referring again to FIG. 3, the method 300 may include operation 301 of determining a rest period OCV V_{rOCV} during a rest period of the battery (e.g., the battery 150 of FIG. 1). In an example, in the rest period, when the device (e.g., the device 100 of FIG. 1) is in a switch off mode for example, a value of a current I drawn from the battery by the device 100 may be 0. In another example, in the reset period, for example, when the device is in a flight mode or an idle mode, the value of the current I drawn by the device 100 may be less than a predefined threshold, which may be configurable. In an example, the predefined threshold may be 1/20 of a maximum current value. In an example, the determination unit 410 may determine the rest period OCV V_{rOCV} when a predefined time has elapsed since the beginning of the rest period. Thresholds may be “predefined” in that they are known prior to being used. For example, the determination unit 410 may determine the rest period OCV V_{rOCV} two minutes after the beginning of the rest period. The predefined time is configurable and may vary depending on different types of devices and/or batteries. Known techniques may be used to determine the rest period OCV V_{rOCV}.

Thereafter, the method 300 may perform operation 303 of determining a no-short OCV V^{∞Ω}_{ocv} of a no-short condition based on at least one predetermined parameter, a first state-of-health (SoH) parameter obtained from a BMS, and a first temperature of the battery (e.g., the battery 150 of FIG. 1). The no-short OCV V^{∞Ω}_{ocv} may be an open circuit voltage corresponding to when there is not a short circuit. For example, the determination unit 410 may determine the no-short OCV V^{∞Ω}_{ocv} using Equation 1 below.

V^{∞Ω}_{ocv}=(m2×T+c2)×θ²+m3×T×θ+c3 Equation 1

Here, V^{∞Ω}_{ocv} denotes a no-short OCV, m2, m3, c2, and c3 denote predetermined parameters, T denotes a temperature of the battery, and θ2 and θ denote SoH parameters. Battery parameters being “predetermined” means that a parameter may be determined prior to performance of the method, e.g., at a time of manufacture of a battery. To elaborate on parameters(m2, m3, c2, c3), such parameters may function as fitting parameters, which may be obtained by fitting the OCV voltage as a function of temperature and SOH, using any suitable mathematical analysis tool, e.g., Matlab.

For example, the determination unit 410 may determine the no-short OCV V^{∞Ω}_{ocv} by inputting the first temperature of the battery as T and the first SoH parameter as θ2 and θ into instructions and/or hardware configured as described by Equation 1.

The predetermined parameters define the effect of different temperatures on battery life of the battery. In an example, values of the predetermined parameters may be “predetermined” in the sense that they are determined before the method is performed, e.g., while the battery (e.g., the battery 150 of FIG. 1) is manufactured or designed.

Further, Equation 1 is merely an example for determining the no-short OCV V^{∞Ω}_{ocv}, and other equations may be used to determine the no-short OCV V^{∞Ω}_{ocv}. Further, in an example, the first temperature of the battery (e.g., the battery 150 of FIG. 1) and the first SoH parameter may be obtained from the BMS (e.g., the BMS 140 of FIG. 1). Further, in an example, the no-short OCV V^{∞Ω}_{ocv} may be estimated in operation 303 that is repeated for respective life cycles of the battery (e.g., each life cycle).

Referring again to FIG. 3, the method 300 may include operation 305 of detecting the presence of an internal short in the battery (e.g., the battery 150 of FIG. 1) based on the no-short OCV V^{∞Ω}_{ocv} and the rest period OCV V_{rOCV}. In an example, the detection unit 412 may determine a difference between the no-short OCV V^{∞Ω}_{ocv} and the rest period OCV V_{rOCV}. The difference between the no-short OCV V^{∞Ω}_{ocv} and the rest period OCV V_{rOCV} may be expressed as shown in Equation 2.

PCV_{diff}=V^{∞Ω}_{ocv}−V_{rOCV} Equation 2

In Equation 2 above, OCV_{diff} denotes the difference between the no-short OCV V^{∞Ω}_{ocv} and the rest period OCV V_{rOCV}.

When the difference OCV_{diff} between the no-short OCV and the rest period OCV exceeds a predetermined threshold, the detection unit 412 may determine that a short circuit is present in the battery. The predetermined threshold is configurable and may vary for different types of devices and/or batteries. In some implementations, the predetermined threshold may be 1 millivolt (mV), 2 mV, or 5 mV. When the difference OCV_{diff} between the no-short OCV and the rest period OCV exceeds the predetermined threshold, the method 300 may perform operation 307. Otherwise, the method 300 may end after operation 305.

Operation 307 may extend the rest period of the battery by a predetermined time period based on determining the presence of the short circuit in the battery. Particularly, the extending unit 414 may extend the rest period by a predetermined time period, such as 20 minutes, responsive to the detection unit 412 determining the presence of the short circuit in the battery (e.g., the battery 150 of FIG. 1). The predetermined time period is configurable and may vary for different types of devices.

Continuing with FIG. 3, the method 300 may include operation 309 of determining an extended OCV of the battery for the extended rest period based on the at least one predetermined parameter, a second temperature of the battery, and a second SoH parameter. In an example, the second temperature of the battery (e.g., the battery 150 of FIG. 1) and the second SoH parameter may be obtained from the BMS (e.g., the BMS 140 of FIG. 1). Particularly, the determination unit 410 may obtain the second SoH parameter and the second temperature of the battery 150 from the BMS 140 at the end of the extended rest period and then may determine the extended OCV of the battery 150. In an example, the extended OCV may be determined using Equation 1 or any other suitable equation. For example, the determination unit 410 may determine the extended OCV by inputting the second temperature of the battery as T and the second SoH parameter as θ2 and θ into Equation 1.

Then, the method 300 may include operation 311 of estimating a short circuit resistance Rₛₕₒᵣₜ based on the no-short OCV V^{∞Ω}_{ocv} the at least one predetermined parameter, and the extended OCV. In an example, the estimation unit 416 may determine a difference OCV_{ediff} between the no-short OCV V^{∞Ω}_{ocv} and the extended OCV. Then, the estimation unit 416 may estimate the short circuit resistance Rₛₕₒᵣₜ based on the difference OCV_{ediff} between the no-short OCV V^{∞Ω}_{ocv} and the extended OCV and the at least one predetermined parameter. In an example, the estimation unit 416 may estimate the short circuit resistance Rₛₕₒᵣₜ using hardware and/or instructions configured as described by Equation 3.

$${R}_{short} = \frac{m 1}{O C {V}_{ediff}} \qquad Equation 3$$

Here, m1 denotes a predetermined parameter that defines the effect of different temperatures on battery life of the battery. For example, m1 may define a sensitivity of the battery life to temperature. In an example, these predetermined parameters may be predetermined while the battery (e.g., the battery 150 of FIG. 1) is manufactured or designed.

In another example for determining a short circuit resistance, the estimation unit 416 may determine a no-short slope of the no-short OCV based on at least the first temperature and the first SoH parameter. Then, the estimation unit 416 may determine an extended slope of the extended OCV based on at least the second temperature and the second SoH parameter. In another example, the estimation unit 416 may also use the at least one predetermined parameter to determine the no-short slope and the extended slope. For example, the estimation unit 416 may determine the no-short slope and the extended slope using one of the equations below.

$${OCV}_{slope} = m 2 \times T + c 2 \times θ 2 + m 3 \times T \times θ + c 3 \qquad Equation 4$$

$${OCV}_{s l o p e} = m 2 \times T 2 + m 3 \times T + m 4 \qquad Equation 5$$

$${O CV}_{slope ( θ )} = \frac{{OCV}_{slope}}{a \times {θ}^{b} + c \times {θ}^{d}} \qquad Equation 6$$

Here, OCVₛₗₒₚₑ denotes the no-short slope of the no-short OCV, OCV_{slope(θ)} denotes the extended slope of the extended OCV, m2, m3, m4, c2, c3, a, b, c, and d denote predetermined parameters, T denotes the temperature of the battery, T2 denotes a temperature of the device, and θ2 and θ denote the SoH parameters.

It should be noted that the predetermined parameters define the effect of different temperatures on battery life. In an example, these predetermined parameters may be predetermined while the battery (e.g., the battery 150 of FIG. 1) is manufactured or designed.

It should be noted that the estimation unit 416 may use the first temperature and the first SoH parameter while the no-short slope is calculated. Similarly, the estimation unit 416 may use the second temperature and the second SoH parameter while the extended slope is calculated. Further, it should be noted that Equations 4, 5, and 6 express only a few examples for determining the no-short slope and the extended slope. Any other known equations may be used to determine the no-short slope and the extended slope. In addition, it should be noted that different equations may be used to determine the no-short slope and the extended slope.

Then, the estimation unit 416 may determine a difference OCV_{sdiff} between the extended slope and the no-short slope. Thereafter, the estimation unit 416 may estimate the short circuit resistance based on the difference OCV_{sdiff} between the extended slope and the no-short slope and the at least one predetermined parameter. In an example, the estimation unit 416 may determine the short circuit resistance using one of a plurality of predefined equations. Some examples of the plurality of predefined equations are as follows.

$${R}_{s h o r t} = \frac{m 5 \times θ + m 6}{{OCV}_{sdiff}} \qquad Equation 7$$

$${R}_{s h o r t} = \frac{m 5}{{OCV}_{sdiff}} \qquad Equation 8$$

Here, m5 and m6 denotes predetermined fitting parameters, and θ denotes the SoH parameter.

The predetermined parameters define the effect of different temperatures on battery life of the battery. In an example, these predetermined parameters may be predetermined at a time when the battery (e.g., the battery 150 of FIG. 1) is manufactured or designed.

Further, Equations 7 and 8 express only a few examples for estimating the short circuit resistance. Any other known equations may be used to estimate the short circuit resistance.

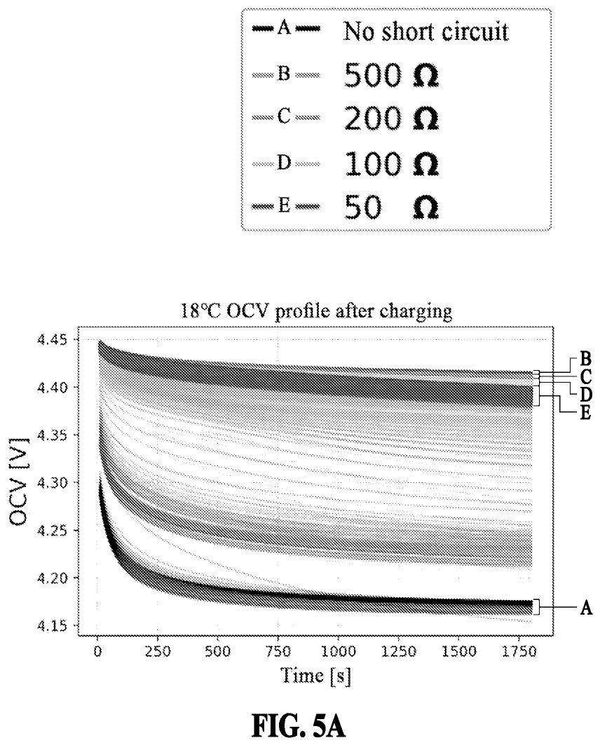

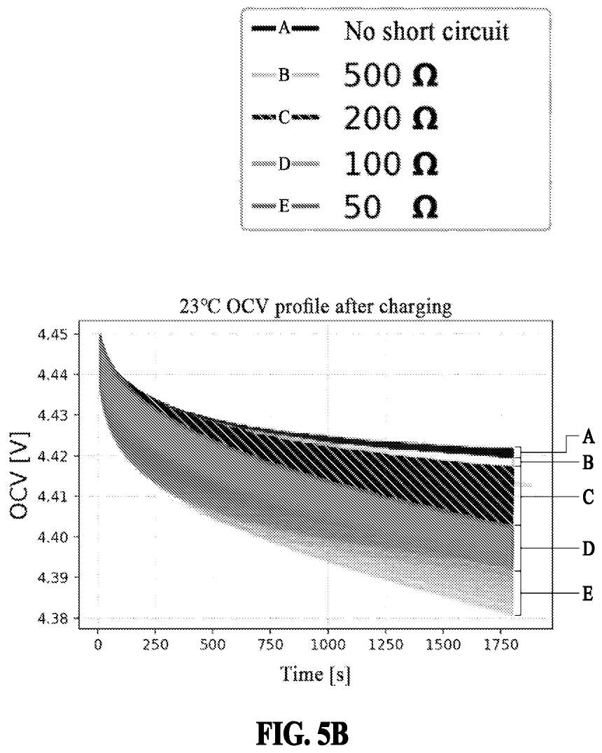

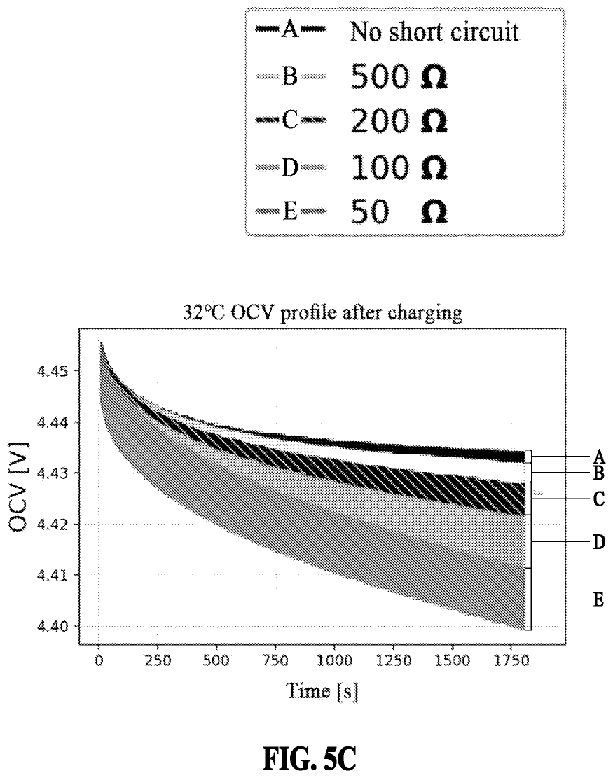

In this way, the techniques of the present disclosure consider different parameters such as a temperature of the battery and an effect a life cycle of the battery on an OCV profile. FIGS. 5A to 5C illustrate examples of the effect of temperature at different short circuit resistances on an OCV profile of a battery, according to one or more embodiments. For example, as illustrated in FIGS. 5A to 5C, an effect of a short circuit resistance, such as 50 Ω, may be greater at a high temperature, such as 32 degrees, compared to a low temperature, such as 18 degrees.

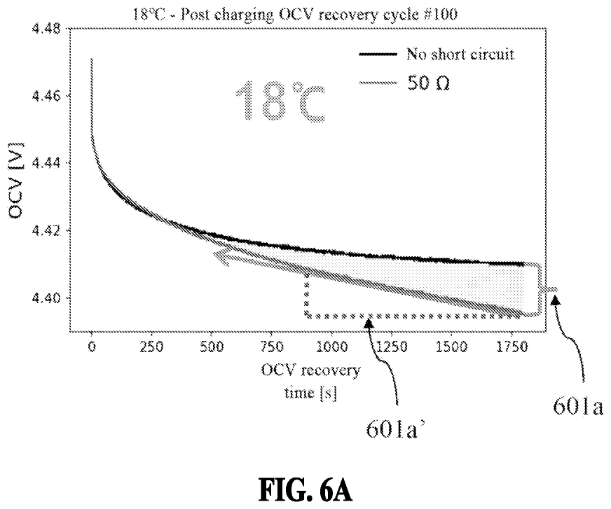

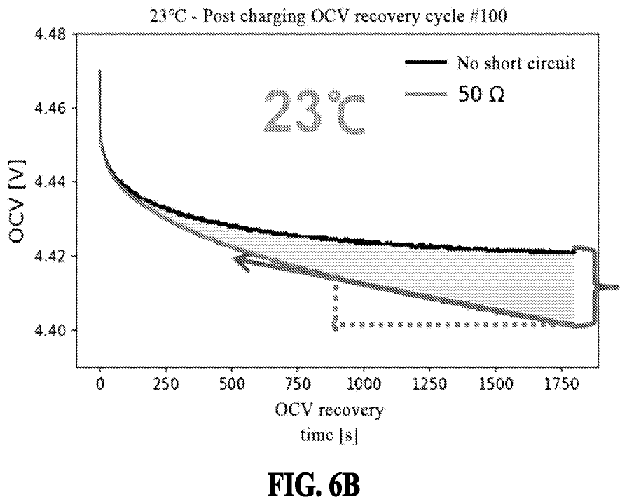

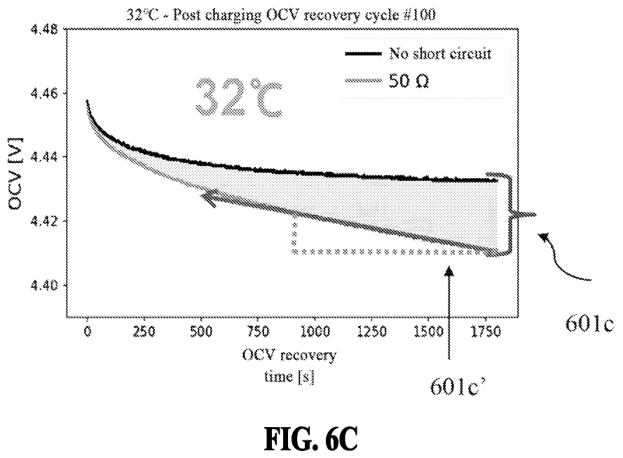

Similarly, FIGS. 6A to 6C illustrate examples of the effect of temperature at different short circuit resistances on an OCV slope and an average OCV value of a battery, according to one or more embodiments. As illustrated in FIGS. 6A to 6C, an effect of a low short circuit resistance, such as 50 Ω, may be greater at a high temperature, such as 32 degrees, compared to a low temperature, such as 18 degrees. For example, an average of OCV values 601a at 18 degrees may be less than an average of OCV values 601c at 32 degrees. Similarly, a difference 601a′ between an OCV slope at a short circuit resistance of 50 Ω and an OCV slope at a no-short circuit at 18 degrees may be less than a difference 601c′ between an OCV slope and an OCV slope at the no-short circuit at 32 degrees.

As the techniques described herein consider the effect of temperature, the short circuit resistance Rₛₕₒᵣₜ estimated using the disclosed techniques is more accurate.

The techniques described herein may be deployed after set intervals of cycle life. The intervals may be adjusted depending on a device. Some devices may require frequent determinations and other devices may not. For large battery packs, the disclosed techniques may be applied one pack at a time. In the case of short detection, depending on the severity of a short, various countermeasures may be deployed. For example, when Rₛₕₒᵣₜ is from 300 to 1000 Ω a reduced operational state-of-charge (SOC) window may be deployed, when Rₛₕₒᵣₜ is from 100 to 300 Ω caution may be provided to a user not to fast charge a device, and when Rₛₕₒᵣₜ is less than 100 Ω the device may be shut down and discharging of the device may be accelerated.

Further, the disclosed techniques may not require any changes in charging protocol/device hardware.

Thus, some implementations of the disclosed techniques may provide some of the following advantages.

1) Existing rest period OCV profiles may be used to determine a short circuit resistance.

2) The disclosed techniques may consider variations in an OCV profile caused by cycle life degradation and temperatures.

3) Even a very soft short of 500 Ω may be estimated.

4) There may be no need to change/modify an existing charging protocol/hardware.

5) A battery may not need to be kept in an open circuit.

6) Safety is enhanced in devices. In particular, since fast charging is known to increase the chance of Li plating and increase the possibility of a micro short, safety may be significantly enhanced in devices that use fast charging.

The computing apparatuses, the electronic devices, the processors, the memories, the displays, the systems, the information output system and hardware, the storage devices, and other apparatuses, devices, units, modules, and components described herein with respect to FIGS. 1-6C are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-6C that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD- Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A method of estimating a short circuit resistance in a battery using open cell voltage (OCV), the method comprising:
determining a rest period OCV for a rest period of the battery;
determining a no-short OCV of a no-short condition based on a predetermined parameter, a first state-of-health (SoH) parameter, and a first temperature of the battery;
determining that an internal short is present in the battery based on the no-short OCV and the rest period OCV, and based thereon extending the rest period of the battery;
determining an extended OCV of the battery for the extended rest period based on the predetermined parameter, a second SoH parameter, and a second temperature of the battery; and
estimating the short circuit resistance based on the no-short OCV, the predetermined parameter, and the extended OCV.

2. The method of claim 1, wherein the predetermined parameter defines the effect of different temperatures on battery life of the battery.

3. The method of claim 1, wherein the determining that an internal short is present in the battery comprises:
determining that a difference between the no-short OCV and the rest period OCV exceeds a threshold.

4. The method of claim 1, wherein the estimating of the short circuit resistance is based on a determined parameter and a difference between the extended OCV and the no-short OCV.

5. The method of claim 1, wherein the estimating of the short circuit resistance comprises:
determining a no-short slope of the no-short OCV based on the first temperature and the first SoH parameter;
determining an extended slope of the extended OCV based on the second temperature and the second SoH parameter; and
estimating the short circuit resistance based on a predetermined parameter and a difference between the extended slope and the no-short slope.

6. The method of claim 5, wherein the short circuit resistance is estimated using a predefined equation.

7. The method of claim 5, wherein the predefined equation comprises a ratio of (i) a sensitivity of battery life of the battery to temperature to (ii) a difference between the no-short OCV and the extended OCV.

8. The method of claim 2, wherein the predetermined parameter is a parameter of the battery corresponding to when the battery was manufactured.

9. The method of claim 1, wherein the first SoH parameter is obtained from a battery management system (BMS).

10. A system for estimating a short circuit resistance in a battery using open cell voltage (OCV), the system comprising:
a processor coupled to a memory and a battery management system (BMS);
the memory storing instructions configured to cause the processor to:
determine a rest period OCV for a rest period of the battery;
determine a no-short OCV of a no-short condition based on a predetermined parameter, a first state-of-health (SoH) parameter obtained from the BMS, and a first temperature of the battery;
determine that an internal short is present in the battery based on the no-short OCV and the rest period OCV, and based thereon, extend the rest period of the battery;
determine an extended OCV of the battery for the extended rest period based on the predetermined parameter, a second SoH parameter obtained from the BMS, and a second temperature of the battery; and
estimate the short circuit resistance based on the no-short OCV, the predetermined parameter, and the extended OCV.

11. The system of claim 10, wherein the predetermined parameter defines the effect of different temperatures on battery life of the battery.

12. The system of claim 10, wherein the instructions are further configured to cause the processor to:
determine that an internal short is present in the battery in response to a difference between the no-short OCV and the rest period OCV exceeding a threshold.

13. The system of claim 10, wherein the instructions are further configured to cause the processor to:
estimate the short circuit resistance based on a predetermined parameter and a difference between the extended OCV and the no-short OCV.

14. The system of claim 10, wherein the instructions are further configured to cause the processor to:
determine a no-short slope of the no-short OCV based on at least the first temperature and the first SoH parameter;
determine an extended slope of the extended OCV based on at least the second temperature and the second SoH parameter; and
estimate the short circuit resistance based a predetermined parameter and a difference between the extended slope and the no-short slope.

15. The system of claim 14, wherein the instructions are further configured to cause the processor to estimate the short circuit resistance using a predefined equation.

16. The method of claim 15, wherein the predefined equation comprises a ratio of (i) a sensitivity of battery life of the battery to temperature to (ii) a difference between the no-short OCV and the extended OCV.

17. The method of claim 10, wherein the predefined parameter is a parameter of the battery corresponding to a time of manufacture of the battery.

18. A method of determining a short circuit resistance of a battery, the method comprising:
determining a first OCV corresponding to a rest period of the battery;
determining, based on a first SOH of the battery and a first temperature of the battery, a second OCV corresponding to a no-short condition of the battery;
based on the first OCV and the second OCV, increasing a rest period duration of the battery;
determining, based on a second SOH of the battery and a second temperature of the battery, a third OCV corresponding to the increased rest period duration; and
determining the short circuit resistance based on the second OCV and the third OCV.

19. The method of claim 18, wherein the determining the second OCV, the third OCV, and the short circuit resistance are further based on a predetermined parameter of the battery.

20. The method of claim 18, wherein the short circuit resistance is determined based on a difference between second OCV and the third OCV.
